(19) United States
(12) Patent Application Publication
(10) Pub. No.: US 2026/0088848 A1
(43) Pub. Date: Mar. 26, 2026

(54) RECEIVER USING FOR MIPI C-PHY

(71) Applicant: SIRIUS WIRELESS PTE. LTD., Singapore (SG)

(72) Inventors: Chun-Pang WU, Taipei City (TW); Kwok LIH, Singapore (SG)

(73) Assignee: SIRIUS WIRELESS PTE. LTD., Singapore (SG)

(21) Appl. No.: 19/334,498

(22) Filed: Sep. 19, 2025

(30) Foreign Application Priority Data
Sep. 20, 2024 (TW) 113135697

(51) Int. Cl. H04B 1/16; H03K 5/00; H03K 5/01; H04B 17/21

(52) U.S. Cl. CPC H04B 1/16; H03K 5/01; H04B 17/21; H03K 2005/00078

(57) ABSTRACT

The present invention provides a low-power receiver for MIPI C-PHY, comprising: an oscillator, a delay cell calibration, an edge detection and pulse generator, and a sampler & wire state decoder. The delay cell calibration is connected to the oscillator signal and receives the frequency signal generated by the oscillator. The edge detection and pulse generator is signal-connected to the delay cell calibration and is used to receive signals transmitted by the MIPI C-PHY. The sampler and wire state decoder is signal-connected to the edge detection and pulse generator and is used to receive signals transmitted by the MIPI C-PHY and output a decoding result. The invention utilizes the known oscillator pulse width (OSC clock high period width, i.e., the duration of the high level of the pulse signal), which is the delay time of one delay cell. After passing through the delay cell calibration circuit, the number of delay cells within the selected oscillator OSC cycle time can be determined. With the known data rate, a selection code is sent to the same delay cell in the edge detector to obtain the delay time for edge pulse generation. The edge pulse is sent to the sampler for data sampling, and after sampling, the state of the decoding action is determined.

### TECHNICAL FIELD

The present invention relates to a low-power receiver used for receiving MIPI C-PHY signals.

### BACKGROUND

MIPI C-PHY receivers are commonly used in scenarios of high-speed serial data transmission, such as cameras and displays in mobile devices. They are also applicable in other embedded systems, such as in-vehicle entertainment systems, smart home devices, etc. A C-PHY receiver typically includes a front-end receiver and a digital logic circuit. The front-end receiver is mainly responsible for receiving signals on the C-PHY transmission lines and converting them into voltage waveforms. The digital logic circuit is responsible for decoding and processing the received signals. The decoder must be able to convert the C-PHY signals into digital data, perform timing verification and error detection, and also support various control and configuration settings to meet application needs. As the devices or applications supported emphasize speed, how to achieve higher read speed under low power consumption is a current technical challenge to be overcome.

### SUMMARY OF THE INVENTION

In view of the above, the present invention provides a receiver for MIPI C-PHY, comprising: an oscillator, a delay cell calibration, an edge detection & pulse generator, and a sampler & wire state decoder.

The delay cell calibration is connected to the oscillator signal and receives the frequency signal from the oscillator. The edge detection and pulse generator is signal-connected to the delay cell calibration and is used to receive signals transmitted by the MIPI C-PHY. The sampler & wire state decoder is signal-connected to the edge detection and pulse generator and is used to receive signals transmitted by the MIPI C-PHY and output a decoding result.

The invention leverages the known oscillator pulse width (OSC clock high period width, i.e., the duration of the pulse signal high level), which is the delay time of one delay cell. After the signal passes through the delay cell calibration circuit, it is possible to determine how many delay cells are present in a selected oscillator OSC cycle. Then, according to the known data rate, a selection code is sent to the same delay cell in the edge detector to obtain the delay time for generating an edge pulse.

This edge pulse is sent to the sampler for data sampling, after which the state of a decoding action is judged.

The advantage of this approach is its applicability to all serializers/deserializers (SerDes) requiring timing sequence, allowing for background calibration, delay cell PVT insensitivity (low sensitivity to process, voltage, and temperature), while fulfilling the low power requirements of MIPI.

### BRIEF DESCRIPTION OF THE DRAWINGS

FIG. 1 is a schematic diagram of the present embodiment.

FIG. 2 is a comparison schematic of decoding actions in the present embodiment.

FIG. 3 is another schematic diagram of the present embodiment.

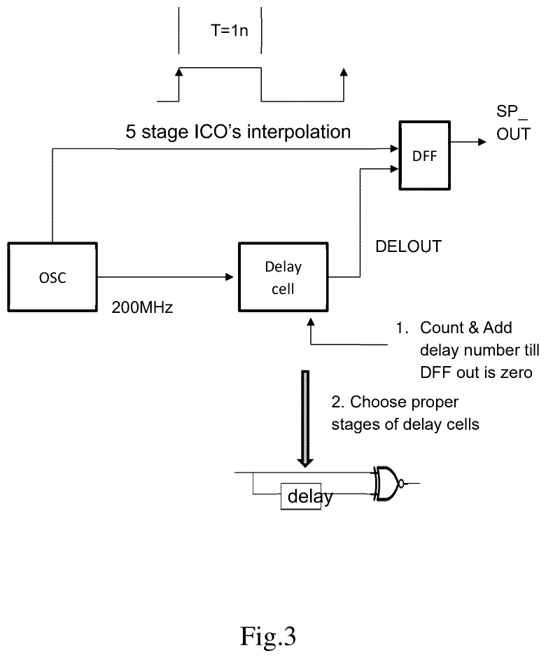

FIG. 4 is a schematic diagram related to sampling by the sampler & wire state decoder in the present embodiment.

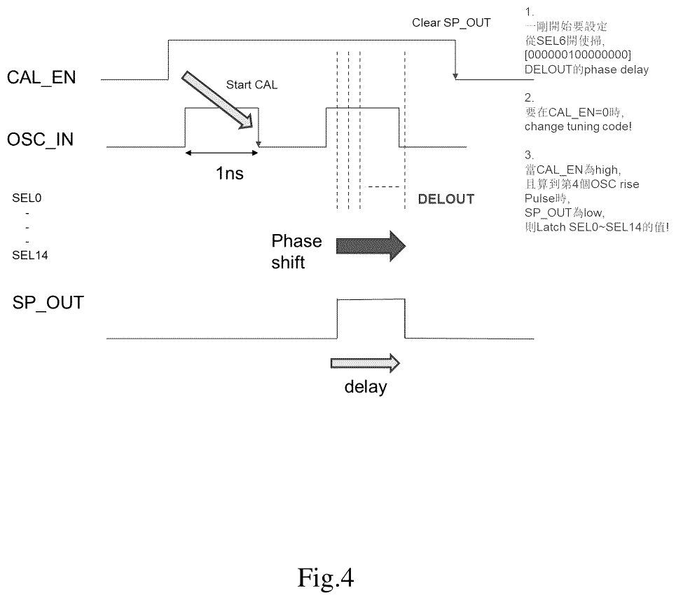

### DETAILED DESCRIPTION OF THE INVENTION

The present invention provides a receiver 1 for MIPI C-PHY, comprising: an oscillator 10, a delay cell calibration 20, an edge detection & pulse generator 30, and a sampler & wire state decoder 40.

The oscillator 10 is configured to generate a fixed clock signal and define the pulse width (the high period width of the OSC clock, i.e., the duration of the pulse signal high level), which is the delay time of one delay cell.

The delay cell calibration 20 is connected to oscillator 10, receives the clock signal generated thereby, and acquires the pulse width (i.e., the delay time of one delay cell). The edge detection & pulse generator 30 is signal-connected to delay cell calibration 20, and is configured to receive signals transmitted by the MIPI C-PHY.

The sampler & wire state decoder 40 is signal-connected to edge detection & pulse generator 30, and is configured to receive signals transmitted by the MIPI C-PHY and output a decoding result.

The invention utilizes the known pulse width corresponding to the delay time of one delay cell. After the signal passes through the circuit of delay cell calibration 20, the number of delay cells in the selected oscillator OSC cycle can be determined. With the known data rate, a code is sent to the edge detector in edge detection & pulse generator 30, using the same number of delay cells, to obtain the delay time for generating the edge pulse.

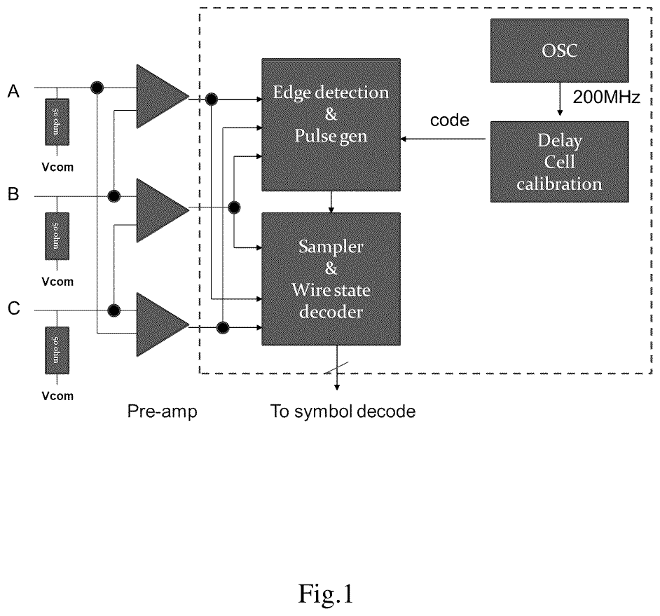

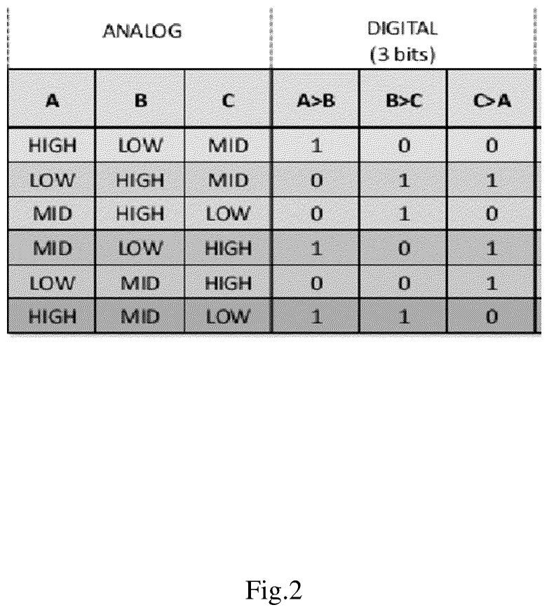

The edge pulse is delivered to the sampler for data sampling. After sampling, it is judged to which state below the decoding action belongs, i.e., whether A>B, B>C, or C>A as in FIG. 1, and the corresponding data as in FIG. 2 is generated. The invention has the advantages of applicability to all serializers/deserializers (SerDes) requiring timing, background calibration, delay cell PVT insensitivity, and compliance with MIPI low power requirements.

The invention leverages the known oscillator pulse width (i.e., OSC clock high period width), which is the delay time of one delay cell. After passing through the delay cell calibration circuit, it is possible to determine how many delay cells are in the selected oscillator OSC cycle time (e.g., every 100 ns). Then, with the known data rate, a selection code is sent to the same delay cell in the edge detector to obtain the delay time of edge pulse generation. The edge pulse is sent to the sampler for data sampling, and after sampling, the state of the decoding action is determined.

The advantage of this approach is its applicability to all serializers/deserializers (SerDes) requiring transmission timing, allowing for background calibration, delay cell PVT insensitivity, and fulfillment of the low power requirements set by MIPI.

In the embodiment of the invention, when the chip powers on, the delay cell calibration 20 performs a calibration operation.

Assume the delay cell is divided into many stages. At the beginning, start with a stage with fewer delay cells, such as scanning from SEL6, DELOUT phase delay. After a period, the delay cell outputs the same 200 MHz rising edge (SP_OUT). The DFF may trigger on the duty high cycle of the OSC output, causing the DFF to output “1”. Gradually increase the DELOUT output phase, choose SEL6˜SEL14, and let the DFF hit the duty low cycle of the OSC 200 MHz. When SP_OUT outputs logic “1”, after adjusting DELOUT, the DFF output SP_OUT becomes low, thus determining how many stages divide 1 ns of delay cell time.

When CAL_EN is high and the 4th oscillator rising pulse (OSC rise Pulse) is counted, SP_OUT is low, then the values of SEL0˜SEL14 are latched.

When CAL_EN is 0, tuning code adjustment is performed. DCDL will exhibit glitches; therefore, the low pulse duty of CAL_EN should last at least 10 ns.

Duplicate five stages of delay cell into ED (up to SEL5).

When the delay cell of ED selects the output of ND3O or ND5O, SEL1 or SEL3 needs to be turned on.

Digital control must be able to calculate the 15 bits (SEL0˜SEL14) latched by the DC_CAL circuit, and convert to the number of stages in the ED delay cell. The temperature sensor information can be sent to the ED. At high temperature, the number of delay cells is reduced.

From the embodiment above, it can be seen that the invention, through the configuration of the oscillator, improves the overall data transmission speed, significantly increases the data quantity transmitted, and maintains low power performance.

### Description of Symbols

10 . . . Oscillator
20 . . . Delay cell calibration
30 . . . Edge detection & pulse generator
40 . . . Sampler & wire state decoder

1. A receiver using for MIPI C-PHY, comprising:
an oscillator;
a delay cell calibration, connected to the oscillator signal and receiving the frequency signal generated by the oscillator;
an edge detection & pulse generator, signal-connected to the delay cell calibration and configured to receive signals transmitted by the MIPI C-PHY;
a sampler & wire state decoder, signal-connected to the edge detection & pulse generator, configured to receive signals transmitted by the MIPI C-PHY and output a decoding result.

2. The receiver using for MIPI C-PHY according to claim 1, wherein the edge pulse generator delivers the edge pulse to the sampler & wire state decoder for data sampling.

3. The receiver using for MIPI C-PHY according to claim 2, wherein the oscillator is used to generate a fixed clock signal and to define a pulse width that is the delay time of one delay cell.
